(19) United States
(12) Patent Application Publication
(10) Pub. No.: US 2024/0274742 A1
(43) Pub. Date: Aug. 15, 2024

(54) Avalanche Photodiode with Cascaded Multiplication Layers for High Speed and Wide Dynamic Range Applications

(71) Applicant: National Central University, Taoyuan City (TW)

(72) Inventor: Jin-Wei Shi, Taoyuan City (TW)

(21) Appl. No.: 18/126,159

(22) Filed: Mar. 24, 2023

(30) Foreign Application Priority Data
Feb. 13, 2023 (TW) 112105009

(51) Int. Cl. H01L 31/107; H01L 31/18

(52) U.S. Cl. CPC H01L 31/1075; H01L 31/1844

(57) ABSTRACT

An avalanche photodiode (APD) with cascaded multiplication layers (M-layer) is provided. The APD is applied to high speed and wide dynamic range applications. It has an epitaxial-layers structure. The structure is formed by inserting at least one charge layer into a single M-layer. The single M-layer is thus sliced into at least two layers, a first and a second M-layers, of different thicknesses. Thus, edge breakdown is suppressed and the increase of dark current caused by M-layer reduction is relieved for high speed performance.

### TECHNICAL FIELD OF THE INVENTION

The present invention relates to an avalanche photodiode (APD); more particularly, to, through slicing, making the area of breakdown actually happened very thin in multiplication layer (M-layer) yet the overall thickness of the M-layer not very thin at all, and, at the same time, reducing edge electric field to zero for preventing edge leakage channels, where the pressure caused by dark current increase owing to M-layer reduction is relieved.

### DESCRIPTION OF THE RELATED ARTS

The spread of over-the-top services and 5G mobile front-haul networks are driving the bandwidth demands of optical communication channel. Currently, a 400 gigabits per second (Gb/s) Ethernet system using pulse amplitude modulation (PAM-4) format has been developed, where each channel has a Gbaud format to meet the requirement of faster data rate. However, when the link distance exceeds 40 kilometers, the limited optical power output of electro-absorption-modulated laser transmitter and the sensitivity of the receiver based on p-i-n photodiode (PD) will limit the distribution of optical power required for maintaining such a high data rate. APD has wider optical-to-electrical (O-E) frequency and higher sensitivity than traditional PD, which is proved to be an effective way for relieving the receiver issue described above.

Recently, it is found that an APD based on silicon/germanium (Si/Ge) exhibits excellent dynamic and static performances at a transfer rate greater than 106 Gb/s per channel. As compared to its III-V counterparts, the Si/Ge APD shows higher dynamic performance, which is mainly due to the fact that the multiplication of the indium aluminum arsenide (In_{0.52}Al_{0.48}As) carrier occurred within the Si M-layer is better than that of III-V M-layer. However, this type of APD is usually grown on a Si substrate with mismatched crystal grids, whose interface defects become a challenge affecting reliability under demanding operating conditions like a non-cooling environment or a high-power lighting (about milliwatt (˜mW)).

In addition to the PAM-4 preparation format, tuned communication solutions have become the alternatives for transmissions greater than 106 Gb/s. However, the PD or APD in a tuned receiver needs to maintain high speed and high linearity under a strong (˜mW) local oscillator (LO) pump power for ensuring high sensitivity performance. It is proved that, as compared to the traditional p-i-n PD used in tuned applications (such as FMCW lidar), a higher signal-to-noise ratio and a lower LO power can be obtained with an APD based on In_{0.52}Al_{0.48}As. These requirements leads to the development of high-speed III-V APDs with high linearity and reliable high power. For ensuring the increase of frequency bandwidth and saturated power of the APD, the thicknesses of absorber layer and M-layer need to be gradually reduced, yet with the cost of lower responsivity. According to related reports, regarding the waveguide-type APDs using thin absorber layer, the trade-off between bandwidth and responsivity is moderated and the gain-bandwidth product is further improved.

By increasing an appropriate absorption length, high responsivity is maintained for this kind of APD. However, an APD of edge-coupled waveguide usually has a narrower alignment tolerance than a vertically-illuminating counterpart (5 μm vs. 25 μm), which is because of the smaller diameter of optical waveguide. Back-illuminated ADPs are alternatives for further enhancing the responsivity of topside-illuminated APD, because the incident light signal passes through dual channels of the topmost contact metal which are used as reflector. Yet, the inverted chip bonding package used for back-illumination usually produces parasitic capacitance, which reduces the pure O-E frequency of PD.

As is described above, a general high-speed APD acquires a reduced thickness of M-layer with the cost of raised dark current. Although the thinner component manufactured for APD obtains the faster speed, the obstruction of breakdown may be easily happened on trying to manufacture the component ultra-thin. Hence, the prior arts do not fulfill all users' requests on actual use.

### SUMMARY OF THE INVENTION

The main purpose of the present invention is to, through slicing, make the area of breakdown actually happened very thin in M-layer yet the overall thickness of the M-layer not very thin at all, and, at the same time, reduce edge electric field to zero for preventing edge leakage channels; and, thus, the pressure of increased dark current brought by the reduction of M-layer is relieved.

To achieve the above purpose, the present invention is an APD with cascaded M-layers for high speed and wide dynamic range applications, where an epitaxial-layers structure is formed by inserting at least one charge layer into a single M-layer to slice the single M-layer into at least two layers, a first and a second M-layers, of different thicknesses for suppressing edge breakdown to relieve the pressure caused by dark current increase owing to M-layer reduction for high speed performance. Accordingly, a novel APD with cascaded M-layers for high speed and wide dynamic range applications is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1A and FIG. 1B are the sectional and top-down views showing the preferred embodiment according to the present invention;

FIG. 2 is the view showing the electric field distributions in the AA′ direction of FIG. 1 under the different breakdown voltages;

FIG. 3A˜FIG. 3C are the views showing the measured dark currents, photocurrents, and operation gains and biases of Device A, Device B, and Device C under the different optical pumping powers, respectively; and

FIG. 4A˜FIG. 4C are the views showing the saturated powers of the photo-generated frequency outputs of Device A, Device B, and Device C measured under the different biases at 30 GHz by using the heterodyne beat device.

### DESCRIPTION OF THE PREFERRED EMBODIMENT

The following description of the preferred embodiment is provided to understand the features and the structures of the present invention.

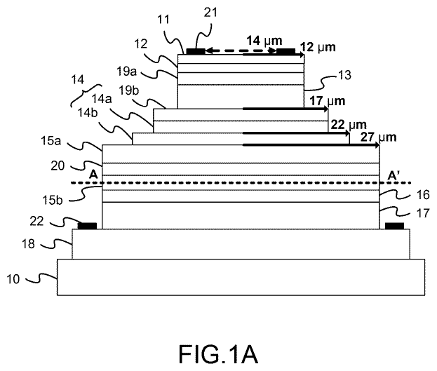

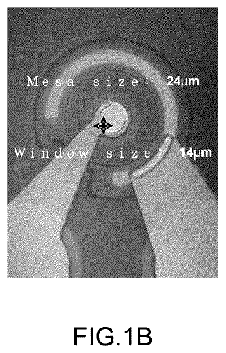

Please refer to FIG. 1A to FIG. 4C, which are sectional and top-down views showing a preferred embodiment according to the present invention; a view showing electric field distributions in the AA′ direction of FIG. 1 under different breakdown voltages; views showing measured dark currents, photocurrents, and operation gains and biases of Device A, Device B, and Device C under different optical pumping powers, respectively; and views showing the saturated powers of photo-generated frequency outputs of Device A, Device B, and Device C measured under different biases at 30 GHz by using a heterodyne beat device. As shown in the figures, the present invention is an avalanche photodiode (APD) with cascaded multiplication layers (M-layer) for high speed and wide dynamic range applications, comprising a P-type contact layer 11, a P-type window layer 12, a P-type graded absorber layer 13, a composite charge layer 14, a plurality of M-layers 15a, 15b, an N-type charge layer 16, a transport layer 17, and an N-type contact layer 18. Therein, two graded bandgap layers 19a, 19b are separately inserted at an interface between the P-type window layer 12 and the P-type graded absorber layer 13 and at an interface between the P-type graded absorber layer 13 and the composite charge layer 14, separately, to be grown on a semi-insulating or conductive semiconductor substrate 10; the plurality of M-layers 15a, 15b comprises a first M-layer 15a and a second M-layer 15b; a P-type charge layer 20 is further set between the first M-layer 15a and the second M-layer 15b; a cathode electrode 21 is set above the P-type contact layer 11; and an anode electrode 22 is set above the N-type contact layer 18. Thus, a novel APD with cascaded M-layers for high speed and wide dynamic range applications is obtained.

The epitaxial-layers structure is formed by inserting at least one charge layer into a single M-layer to slice the single M-layer into at least two layers, a first M-layer 15a and a second M-layer 15b, of different thicknesses for suppressing edge penetration to relieve the pressure caused by dark current increase owing to M-layer reduction for high speed performance.

In a state-of-use, the epitaxial-layers structure further comprises a third M-layer.

On using, the present invention has a design of a plurality (at least two) of continuously-stacking M-layers. Take the growing of double layers as an example. A charge layer 20 is inserted between two M-layers 15a, 15b to form a first M-layer 15a and a second M-layer 15b, so that the area actually used for avalanching is limited to the thinner second M-layer 15b. In this way, a very thin M-layer is equivalently used, but the M-layer in overall (the first M-layer+the second M-layer) is not actually grown very thin; and, so, it is not easy for current to break through. Furthermore, the present invention etches out all of the part of the charge layer at the edge of the first M-layer 15a to reduce the edge electric field to 0, where the dark current problem of traditional high-speed APD is fundamentally overcome.

The following descriptions of the state-of-uses are provided to understand the features and the structures of the present invention.

An APD top-illuminated with M-layers for high speed and wide dynamic range applications has its structure shown in FIG. 1A. The epitaxial-layers structure, from top to bottom, comprises a P⁺-type indium gallium arsenide (In_{0.53}Ga_{0.47}As) contact layer 11; a P⁺-type indium phosphide (InP) window layer 12; a P-type In_{0.53}Ga_{0.47}As absorption layer 13 with a thickness smaller than 2 microns (μm); a composite P-type In_{0.52}Al_{0.48}As/InP charge layer 14; two undoped In_{0.52}Al_{0.48}As M-layers 15a, 15b with a total thickness smaller than 1 μm; an N-type In_{0.52}Al_{0.48}As charge layer 16; an undoped InP transport layer; and an N⁺-type InP contact layer 18. Besides, a P⁺-type and an undoped indium aluminum gallium arsenide (InAlGaAs) graded bandgap layers 19a, 19b are inserted at an interface between the window layer 12 and the graded absorber layer 13, and at an interface between the graded absorber layer 13 and the composite charge layer 14, respectively; and the epitaxial-layers structure is grown on a semi-insulating InP substrate 10. To meet the requirement of APD frequency bandwidth, the present invention further reduces the thickness of the graded absorber layer 13 and overall of the M-layers 15a, 15b. In a traditional APD structure, such a bandwidth enhancement usually comes with the cost of reduced responsivity and increased dark current. However, the present invention uses a structure with two M-layers to release the trade-off between speed, dark current, and responsivity. The whole M-layer is divided into two parts, which are the first M-layer 15a and the second M-layer 14b with an extra P-type In_{0.52}Al_{0.48}As charge layer 20 in between.

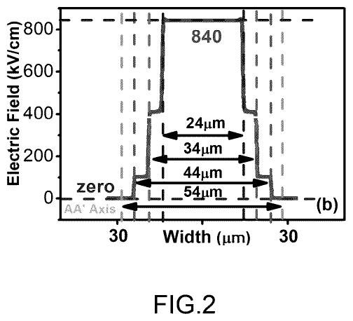

The epitaxial-layers structure introduces a stepwise electric field distribution, where most of the avalanche processes are limited to the extremely thin second M-layer 15b having the highest electric field in the entire epitaxial-layers structure for shortening the delay time of avalanching with a high gain-bandwidth product and a low excessive noise. Besides, as compared with directly reducing the thickness of a single M-layer of a traditional APD to the same thickness of the second M-layer 15b of the present invention, the design of adding the first M-layer 15a effectively suppresses tunneling leakage and provides lower dark current in overall. At the same time, the present invention uses the composite charge layer 14, which comprises two layers (a P-type In_{0.52}Al_{0.48}As charge layer 14a and a P-type InP charge layer 14b) with a heterogeneous interface, to ensure zero edge electric field of the sidewall of the second M-layer 15b at bottom for suppressing edge breakdown. Selective chemical wet etching is used between these two P-type charge layers 14a, 14b to accurately etch out the composite charge layer 14 above the single M-layer for obtaining the zero electric field at the edge. The simulated electric field distribution of the structure is shown in FIG. 2.

Furthermore, by inserting the InP transport layer 17 below the M-layer, the burden of RC bandwidth limit is reduced for allowing further expanding the effective diameter of APD and thus obtaining a great adjustment limit for packaging APD. As compared with the transport layer of In_{0.52}Al_{0.48}As traditionally used, the InP transport layer 17 used in the present invention provides a greater punch-through drift speed and further widens the tradeoff between the active area and the RC bandwidth limit. In addition, as compared with the reverse P-side-down APD, the P-side-up APD according to the present invention further increases saturation power output. Hence, because the InP substrate at bottom is close to the second M-layer 15b having the highest electric field, the heat of the present invention is effectively dissipated.

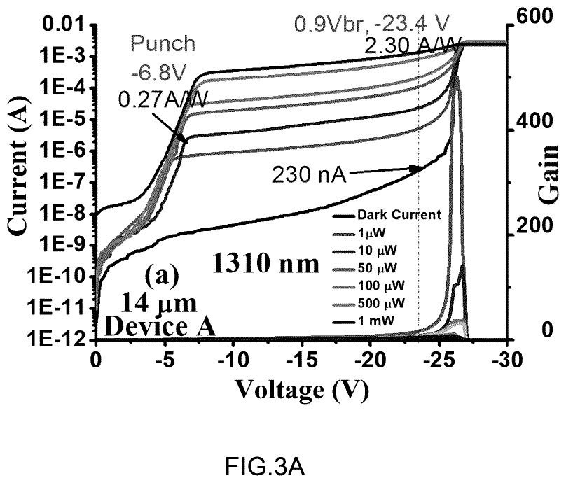

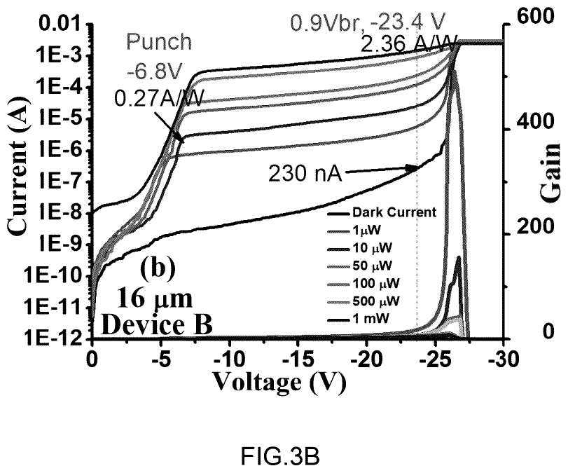

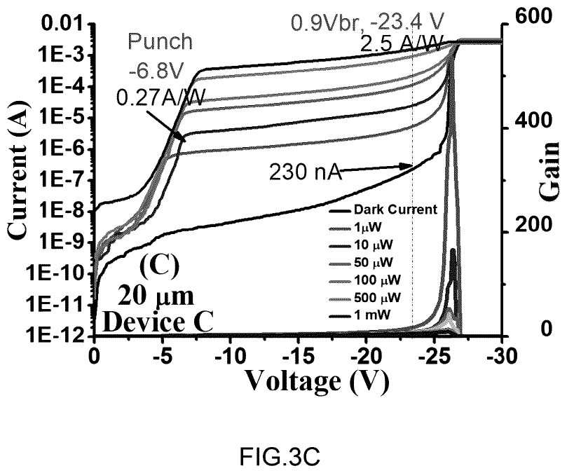

FIG. 1A shows a five-level platform used in the present invention. As shown in the figure, to accurately extract the internal carrier transmission times in the epitaxial-layers structures of the APDs according to the present invention, Device A, Device B, and Device C with three different diameters (14, 16, and 20 μm) of first P-type platform are fabricated. During the fabrication, the first platform with a diameter of 24 μm is etched out on a P-type graded absorber layer 13. Then, the second perform with a diameter of 34 μm is etched out to be ending at an InP charge layer 14b by performing a selective wet etching. The thin third platform with a diameter of 44 μm is formed with an InP charge layer 14b above a first M-layer 15a. At last, the multiplication area is etched through until an N-type InP contact layer 18 to obtain a fourth platform with a diameter of 54 μm. A detailed view of the platforms is shown in FIG. 1A. The present invention uses the Silvaco TCAD simulation software to simulate electric field distribution. By properly selecting the doped density of the charge layer, unnecessary avalanche breakdown is avoided, where, as a result, the electric field of 150 kilovolts per centimeter (kV/cm) in the In_{0.53}Ga_{0.47}As graded absorber layer 13 and the electric field of 500 kV/cm in an InP transport layer 17 are far smaller than the corresponding critical fields. The measured I-V curves are shown in FIG. 3. FIG. 2 shows the electric field in the horizontal A-A′ direction of the second M-layer 15b at bottom calculated under a breakdown voltage (breakdown voltage (Vbr): −26 V). It is clearly observed that the horizontal electric field (840 kV/cm) in the second M-layer 15b at bottom is well limited to the range of the front P-type platform with a diameter of 24 μm. As described above, the horizontal electric field is drastically reduced to zero at the edge of the second M-layer 15b closest to the bottom. FIG. 1B shows a top-down view of the present invention fabricated with an active platform having a diameter of 24 (14) μm.

FIG. 3A to FIG. 3C separately show the bias-related dark currents, photocurrents, and operation gains of Device A, Device B, and Device C having different platform diameters (14, 16, and 20 μm) measured under different optical pumping powers. As shown in the figures, the measured punch-through voltage (Vpt) and Vbr are about −6.8 V and −26 V, respectively. As compared to a report of the APD with an optical-to-electrical (O-E) bandwidth close to 3 dB (>1 HA at 0.9 Vbr) for 106 gigabits per second (Gbit/see) applications, the dark current at 0.9 Vbr expressed by the present invention is much lower—about 200 nA; and, as compared to about 1 μm described in general traditional documents, the dark current of the present invention is pressurized to a very low level. This is attributed to the unique design of cascaded M-layers and the elimination of edge breakdown by adding a special composite charge layer. As shown in FIG. 1A, the M-layers (the first M-layer+the second M-layer) of the present invention are grown to obtain a total thickness slightly thicker; but the second M-layer for avalanching in actual is directly made thin—the thinner, the faster in speed. Thus, not only the high speed is maintained, but also the dark current is reduced. Under a low luminous power (˜10 microwatts (μW)) with a 1.31 μm wavelength and 0.9 Vbr, the three devices of Device A, Device B, and Device C have measured responsivities of 2.3, 2.36, and 2.5 amperes per watt (A/W), respectively. Under a 10 μW optical power, gains corresponding to Device A, Device B, and Device C are 7.67, 7.86, and 8.33, respectively. Besides, with the same optical pump power (−20 decibels relative to one milliwatt (dBm)), the maximum gain of the APD provided by the present invention is more than three times greater than the gain and responsivity of a III-V and Si—Ge counterpart (45 A/W vs. 14 A/W). This is attributed to that the double stacking design of the present invention promotes a lower dark current and a more obvious breakdown process.

Device A is excited under a bias voltage of about 0.9 Vbr (−23 V) and a low optical power to show a 3-dB bandwidth of 30 GHz and a responsivity of 2.23 A/W under a gain of MG as 7.43. The APD provided by the present invention obtains the speed and responsivity by its simple structure, which is even better than the III-V counterpart of Japan's NTT Corporation as having the same 14 μm window size, 28 GHz bandwidth, and 1.95 A/W responsivity as shown in Table 1, showing a performance comparison of different APD types.

TABLE I

| Parameter | NTT | | SiFotonics Technology | | Albis (APD20EI) | This work | |
|---|---|---|---|---|---|---|---|
| Reference | 8 | | 6 | | 31 | | |
| Type | Backside-illuminated | | Topside-illuminated | | Topside-illuminated | Topside-illuminated | |
| | | | (Reflector on Backside) | | | | |
| Mesa Size | 14 | μm | 20 | μm | window size 14 μm | 24 μm | |
| | | | | | | (window size 14 μm) | |
| Dark Current (0.9 Vₐ) | 2 | μA | 0.9 | μA | — | 200 | nA |

| | | | | | | |
|---|---|---|---|---|---|---|
| Responsivity | 1.95 | A/W | 3.53 (6.5) A/W | 4 | A/W | 2.23 (3.3) A/W |
| Bandwidth | 28 | GHz | 28 (22) GHz | 20 | GHz | 30 (22) GHz |

| | | | | | | | |
|---|---|---|---|---|---|---|---|
| Optical Saturation Power | — | 0 | dBm | 5 | dBm | 8.8 | dBm |

(Damage Threshold)

In Table 1, Japan's NTT Corporation provides the APD, performing a dark current of 2 μA, a response rate of 1.95 A/W, and a bandwidth of 28 GHz. As compared to this, the APD provided by the present invention has a dark current of 200 nA only, a responsivity of 2.23 A/W, and a bandwidth of 30 GHz, which is superior to Japan's NTT in all aspects of performance and shows better advancement than the APD provided by Japan's NTT.

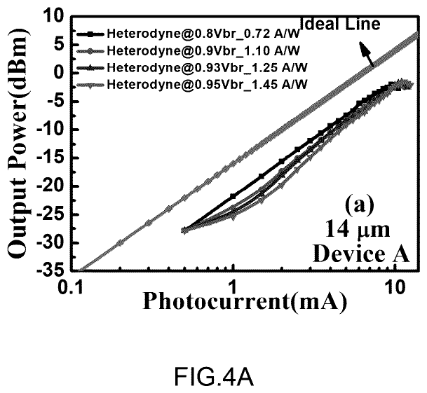

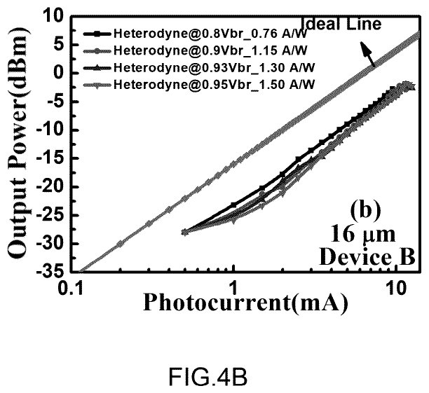

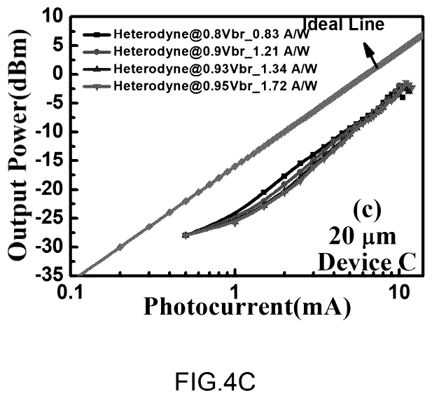

The China's SiFotonics Corporation in Table 1 provides an APD, which has not only a complex producing procedure and a large dark current, but also a saturated optical power set at 0 dBm. As compared to this, the APD provided by the present invention has not only an ultra-low dark current of 200 nA but also a saturated optical power of 8.8 dBm. As observed in the relationship between optical power and photocurrent shown in FIG. 4, the output power of the APD provided by the present invention is still unsaturated even under a strong photocurrent of 10 milliamperes (mA). On the contrary, SiFotonics' is saturated on reaching 0 dBm, while the present invention has better performances on raising overload and increasing optical power.

FIG. 4A to FIG. 4C show the saturated powers of photo-generated frequency outputs of Device A, Device B, and Device C measured under different biases at 30 GHz by using a heterodyne beat device. As shown in the figures, with the maximum output power of radio frequency (RF) under 0.95 Vbr, the saturated photocurrents of Device A, Device B, and Device C are 11 mA all the same. For example, the responsivity of Device A measured at a saturated output RF power of −1.8 dBm (corresponding to the high emitting optical power of +8.8 dBm) is approximately 1.5 A/W. When the output photocurrent rises, the measured trajectories under different Vbr's are merged together owing to shorter breakdown delay times and wider O-E frequencies under high power operations. This remarkable improvement in the product of saturated current frequency is mainly due to the increase in speed obtained through merging two M-layers for forming a novel APD without reducing the size of active area. Hence, on being used in a high speed coherent receiver, the APD provided by the present invention has the potential to further improve the signal-to-noise ratio, which, at the same time, needs less optical LO power than p-i-n photodiode. Table 1 shows the standard performances of the APDs having front and end receiving structures with transmissions of 28 or 56 GBaud. As clearly shown in Table 1, the present invention has a simple structure, which appears to have an excellent bandwidth responsivity product and a record-high saturated current bandwidth product.

As is described above, the present invention has an increased overload (FIG. 4), an ultra low dark current of 200 nA (FIG. 3), and a bandwidth reaching 30 GHz or even higher. In FIG. 3, responsivities of 2.3, 2.36, and 2.5 A/W are also found as better than those of the device provided by Japan's NTT; and the advantages of the present invention like fast speed, etc. are obviously shown.

To sum up, the present invention is an APD with cascaded M-layers for high speed and wide dynamic range applications, where, through slicing, the area where breakdown is actually happened in M-layer is made very thin, yet the overall thickness of the M-layer is not that thin; at the same time, edge electric field is reduced to zero for preventing edge leakage channels; and, thus, the pressure of increased dark current brought by the reduction of M-layer is relieved.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. An avalanche photodiode (APD) with cascaded multiplication layers (M-layer) for high speed and wide dynamic range applications,
wherein an epitaxial-layers structure is obtained by inserting at least one charge layer into a single M-layer to slice said single M-layer into at least two layers, a first and a second M-layers, of different thicknesses to suppress edge breakdown to relieve the pressure caused by dark current increase owing to M-layer reduction to obtain high-speed performance.

2. The APD according to claim 1,
wherein said epitaxial-layers structure further obtains a composite charge layer above said single M-layer; and said composite charge layer comprises two layers of materials having heterogeneous contact surfaces, wherein said composite charge layer above said single M-layer is accurately etched by selective wet chemical etching to reduce the edge field on the side wall of said second M-layer to zero.

3. The APD according to claim 1,
wherein, from top to bottom, said epitaxial-layers structure comprises a P-type contact layer, a P-type window layer, a P-type graded absorber layer, a composite charge layer, a plurality of M-layers, an N-type charge layer, a transport layer, and an N-type contact layer; two graded bandgap layers are separately inserted at an interface between said window layer and said graded absorber layer and at an interface between said graded absorber layer and said plurality of M-layers; said plurality of M-layers comprises said first M-layer and said second M-layer; and a P-type charge layer is further obtained between said first M-layer and said second M-layer.

4. The APD according to claim 1,
wherein, said epitaxial-layers structure is grown on a semiconductor substrate selected from a group consisting of a semi-insulating semiconductor substrate and a conductive semiconductor substrate.

5. The APD according to claim 4,
wherein said P-type contact layer is of P⁺-type indium gallium arsenide (InGaAs); said P-type window layer is of P⁺-type indium phosphide (InP); said two graded bandgap layers are a layer of P⁺-type indium aluminum gallium arsenide (InAlGaAs) and a layer of undoped InAlGaAs, separately; said P-type graded absorber layer is of P-type doped InGaAs; said composite charge layer is of P-type doped InAlAs and undoped InP; said first M-layer is of undoped InAlAs; said P-type charge layer is of P-type doped InAlAs; said second M-layer is of undoped InAlAs; said transport layer is of undoped InP; said N-type charge layer is of N-type doped InAlAs; and said N-type contact layer is of N⁺-type doped InP.

6. The APD according to claim 4,
wherein said P-type graded absorber layer has a thickness less than 2 microns (μm).

7. The APD according to claim 1,
wherein said first and said second M-layers have thicknesses to be summed to be less than 1 μm.

8. The APD according to claim 1,
wherein said epitaxial-layers structure further comprises a third M-layer.
